(19) United States
(12) Patent Application Publication
(10) Pub. No.: US 2012/0198616 A1
(43) Pub. Date: Aug. 9, 2012

(54) DISTRIBUTED THERMOELECTRIC STRING AND INSULATING PANEL AND APPLICATIONS FOR LOCAL HEATING, LOCAL COOLING, AND POWER GENERATION FROM HEAT

(76) Inventors: Tarek Makansi, Tucson, AZ (US); Michael J. Berman, Tucson, AZ (US); Steven Wood, Tucson, AZ (US); John L. Franklin, Sonoita, AZ (US); Mark N. Evers, Tucson, AZ (US)

(21) Appl. No.: 13/394,288

(22) PCT Filed: Sep. 12, 2011
(86) PCT No.: PCT/US11/51227

§ 371 Date: Mar. 5, 2012

Related U.S. Application Data
(63) Continuation-in-part of application No. 13/101,015, filed on May 4, 2011.
(60) Provisional application No. 61/403,217, filed on Sep. 13, 2010.
(60) Provisional application No. 61/417,380, filed on Nov. 26, 2010.
(60) Provisional application No. 61/433,489, filed on Jan. 17, 2011.
(60) Provisional application No. 61/470,039, filed on Mar. 31, 2011.
(60) Provisional application No. 61/504,784, filed on Jul. 6, 2011.

(51) Int. Cl. A47C 21/04; H05B 3/00; F25B 21/04; H01L 35/28; H01L 35/34

(52) U.S. Cl. 5/423; 136/200; 136/201; 62/3.3; 5/421; 219/201

(57) ABSTRACT

Inexpensive, lightweight, flexible heating and cooling panels with highly distributed thermoelectric elements are provided. A thermoelectric “string” is described that may be woven or assembled into a variety of insulating panels such as seat cushions, mattresses, pillows, blankets, ceiling tiles, office partitions, under-desk panels, electronic enclosures, building walls, refrigerator walls, and heat conversion panels. The string contains spaced thermoelectric elements which are thermally and electrically connected to lengths of braided, meshed, stranded, foamed, or otherwise expandable and compressible conductor. The elements and a portion of compacted conductor are mounted within the insulating panel. On the outsides of the panel, the conductor is expanded to provide a very large surface area of contact with air or other medium for heat absorption on the cold side and for heat dissipation on the hot side.

### CROSS REFERENCE TO RELATED APPLICATIONS

This application claims priority from U.S. application Ser. No. 13/101,015, filed May 4, 2011, which in turn claims priority from U.S. Provisional Application Ser. No. 61/403,217, filed Sep. 13, 2010; U.S. Provisional Application Ser. No. 61/417,380, filed Nov. 26, 2010, U.S. Provisional Application Ser. No. 61/433,489, filed Jan. 17, 2011, and from; U.S. Provisional Application Ser. No. 61/470,039 filed Mar. 31, 2011. This application also claims priority from U.S. Provisional Application Ser. No. 61/504,784 filed. Jul. 6, 2011. The contents of all of the aforesaid applications are incorporated herein by reference.

Thermoelectric modules typically contain densely packed elements spaced apart by 1-3 mm. Typically, up to 256 such elements may be connected in an array that is 2×2 inches (5.08×5.08 cm) in area. When these modules are deployed, large and heavy heat sinks and powerful fans are required to dissipate or absorb the heat on each side. The reasons for these dense prior art configurations are well-founded: small elements with low resistance allow larger current I to flow before the resistive heat (I²R) generated destroys the thermoelectric cooling (pI1 where p=Peltier coefficient). The use of short elements for maximum cooling capacity results in the hot and cold side circuit boards being close together. This proximity results in the high density.

To achieve a low density packing of thermoelectric elements, one could space out these elements on the boards laterally, but then the backflow of heat conducted and radiated through the air between the elements limits the overall performance. Some designs require evacuating the module interior to reduce heat backflow due to air conduction, but vacuum cavities require expensive materials and are prone to leaks. Vacuum materials (like glass and Kovar™) are also hard and easily broken when thin enough to limit their own backflow of heat. Broken glass can lead to safety issues when these modules are used in seat cushions, automobiles, and other environments.

Another problem in spreading out thermoelectric elements is that the rigid connection of elements over large distances causes them to rupture due to sheer stress upon thermal expansion of the hot side relative to the cold side. To solve this problem, other designs have been proposed that use a flexible plastic such as polyimide for the circuit boards, but these materials are too porous to maintain a vacuum.

Another disadvantage of the prior art design of thermoelectric modules is that the high density of heat moved to the hot side results in a temperature gradient through the heat sink, and this temperature delta subtracts from the overall cooling that the module can achieve. In particular, traditional thermoelectric products are not able to reach true refrigeration temperature because of this temperature gradient.

Finally, because prior art thermoelectric modules are placed in a solder reflow oven during assembly, only high-temperature materials may be used. Unfortunately, many desired uses of cooling and heating involve close or direct contact with the human body, for which soft materials, such as cushions, cloths, and flexible foam are preferred, but these materials cannot withstand the high temperatures of a solder reflow oven.

Thermoelectric devices can be as efficient, or even more efficient, than vapor compression cooling systems when the temperature delta is 10 degrees C. or less. For this reason, a strong desire exists to deploy thermoelectric technology for local heating and cooling of occupied spaces and thereby reduce the overall energy consumption needed for personal comfort. The total energy savings of the central A/C or heating system plus the local thermoelectric systems can be 30% or more for such a combination, but the unwieldy implementation of prior-art thermoelectric modules inhibits their use for this purpose.

Most thermoelectric and compressor-based cooling systems today are configured as forced air systems. In order to cool the room to a comfortable 75 F, the forced air needs to be 55 F as it exits the vent. The difference between the 55 F cold side temperature and the outside temperature of 80 F to 110 F means that the delta temperature across a thermoelectric module in a forced-air configuration is so large that its heat-backflow conduction makes its overall efficiency very low. However, if a distributed thermoelectric implementation is used, as disclosed here, the cold side can be in contact with the human body, or in close enough proximity such that the cold side seen by the thermoelectric elements are close to the ideal skin temperature of 86-91 F, hence reducing the temperature delta at the thermoelectric device to a level that makes its efficiency comparable to that of a compressor-based system.

Individuals who sit or lie down for long periods of time experience discomfort from trapped heat between the skin and the contact surface. This trapped body heat leads to unproductive perspiration which accumulates and causes a soggy, sticky feeling. In extreme eases, the moisture weakens the skin and the tissue causing pressure ulcers and sores. Although these skin disorders are fundamentally caused by pressure closing off blood flow to tissues, temperature is also a factor in their formation and severity (see “Skin Cooling Surfaces: Estimating the Importance of Limiting Skin Temperature”, by Charles Lachenbruch, Ostomy Wound Management February 2005). A distributed thermoelectric implementation can be very effective in eliminating the discomfort and reducing or preventing the disorders caused by trapped heat in sitting and lying down positions.

In one example, we show how a string of thermoelectric elements connected by conductors in accordance with the present invention can be used to produce a heated or cooled mattress surface. The resulting mattress uses contact between the expanded conductor and the skin or clothing to remove trapped heat, which is not only more efficient as mentioned earlier, but also is responds much faster than prior art thermoelectric systems that employ a working fluid like water or air. In these prior art systems, the entire volume of the water or air must have its temperature increased or decreased before the user feels a change. For the present invention, the user feels a change as soon as the expanded conductor changes temperature, which can occur in seconds.

Hence, the need exists for a variety of insulating panels to be safely and comfortably improved with thermoelectric capability, such as seat cushions, mattresses, pillows, blankets, ceiling tiles, office/residence walls or partitions, under-desk panels, electronic enclosures, building walls, solar panels, refrigerator walls, freezer walls within refrigerators, or crisper walls within refrigerators.

Devices that generate electricity from renewable sources all have limitations. The ideal power generation technology supplies power 24 hours per day, is low cost, and uses only energy from renewable sources, such as wind, tidal and wave, sunlight, or geothermal pools. The two most common forms of utility-scale renewable power generation are wind turbines and photovoltaic systems.

Photovoltaic (PV) technology has the following limitations: (1) high cost, (2) generates power only when the sun is shining brightly which is less than 33% of the time, (3) introduces transients into the electrical grid when clouds suddenly block the sun, and (4) low efficiency without concentration or dangerous temperatures and light levels with concentration.

Wind turbines have the following limitations: (1) relatively high cost, (2) generates power only when the wind is blowing which is less than 33% of the time on average, (3) introduces transients into the electrical grid when the wind suddenly stops or changes direction, (4) requires very tall and visually unacceptable structures, (5) generates noise, (6) has a random peak capacity time during the day that rarely matches the peak demand time, and (7) has very low land usage at about 4 Kwatts per acre.

Both PV and wind turbines may be supplemented with large batteries to store energy for periods of time when the renewable source is not available, but such storage is very expensive at about $1000 per Kwatt hour. When combined with battery storage to achieve 100% renewable generation, the cost for a renewable PV or wind turbine plant is around $20 per watt, vs. about $10 per watt for a fossil fuel pant including 10 years of fuel costs.

Tidal and wave energy installations require high capital startup costs, and like wind turbines, suffer from variable output and may be visually unacceptable structures if erected near shorelines.

Hence, the need exists for a low-cost electrical power generation capability that can supply power 24 hours per day, 7 days per week, and 365 days per year and only tap renewable energy sources. One preferred embodiment of the invention thermoelectric string and associated panel described herein can accomplish these goals.

Broadly speaking, this invention makes possible thermoelectric capability for a variety of panel materials and enables local/personal heating and cooling that reduces overall energy consumption. In one aspect this invention provides a thermoelectric string that can be woven or inserted into a variety of such panels, including soft and low-temperature panels. In another aspect, this invention also eliminates the need for a large, bulky, heavy, and expensive heat sinks and fans to dissipate heating and cooling. In one aspect this invention combines hardware that moves electrical current with hardware that dissipates thermal energy, thereby saving cost over embodiments such as U.S. Pat. No. 3,196,524. In another aspect this invention provides a common set of hardware to provide low thermal back flow near the thermoelectric elements and simultaneously provides high thermal conduction to ambient air away from the elements. In one embodiment this invention provides a thermoelectric string that can be routed through small holes in the panel to minimize thermal leakage. In another embodiment this invention eliminates the need for vacuum enclosures such as U.S. Pat. No. 3,225,549 of highly-distributed thermoelectric elements and also eliminate the need for wicking fluids such as US 2010/0107657. In a particularly preferred embodiment this invention provides cooling capability and electricity generation for pennies per watt in manufacturing cost. In some embodiments this invention reduces the delta temperature required across the thermoelectric elements to a level that the overall cooling efficiency can be comparable to that of a vapor compression system. In some embodiments, this invention reduces or eliminates discomfort and disorders from trapped heat between human or animal skin and surfaces.

Features and advantages of the present invention will be seen from the following detailed description taken into conjunction with the accompanying drawings wherein like numerals depict like parts, and wherein:

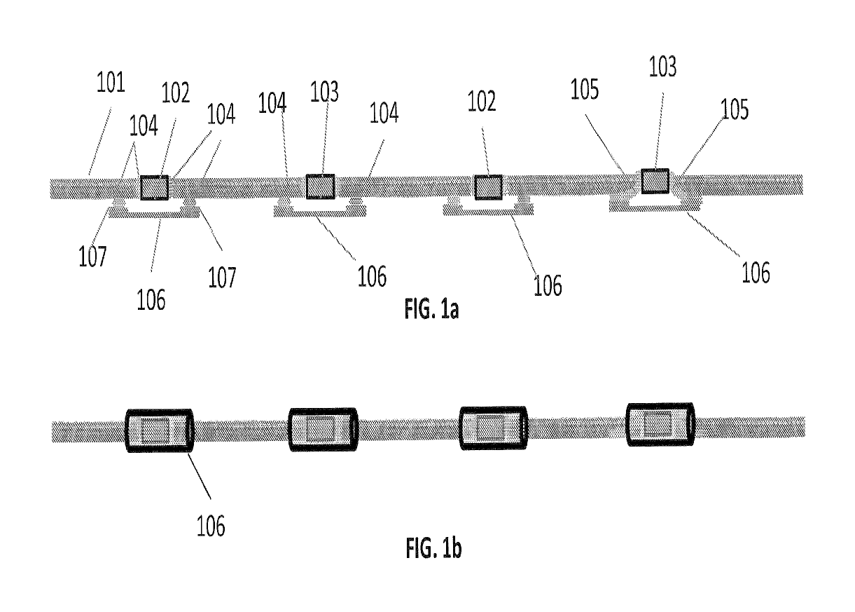

FIG. 1a shows a string of thermoelectric elements connected by lengths of braided wire with a flat (pellet) strain reliefs;

FIG. 1b shows a string of thermoelectric elements connected by lengths of braided wire with tubular strain reliefs

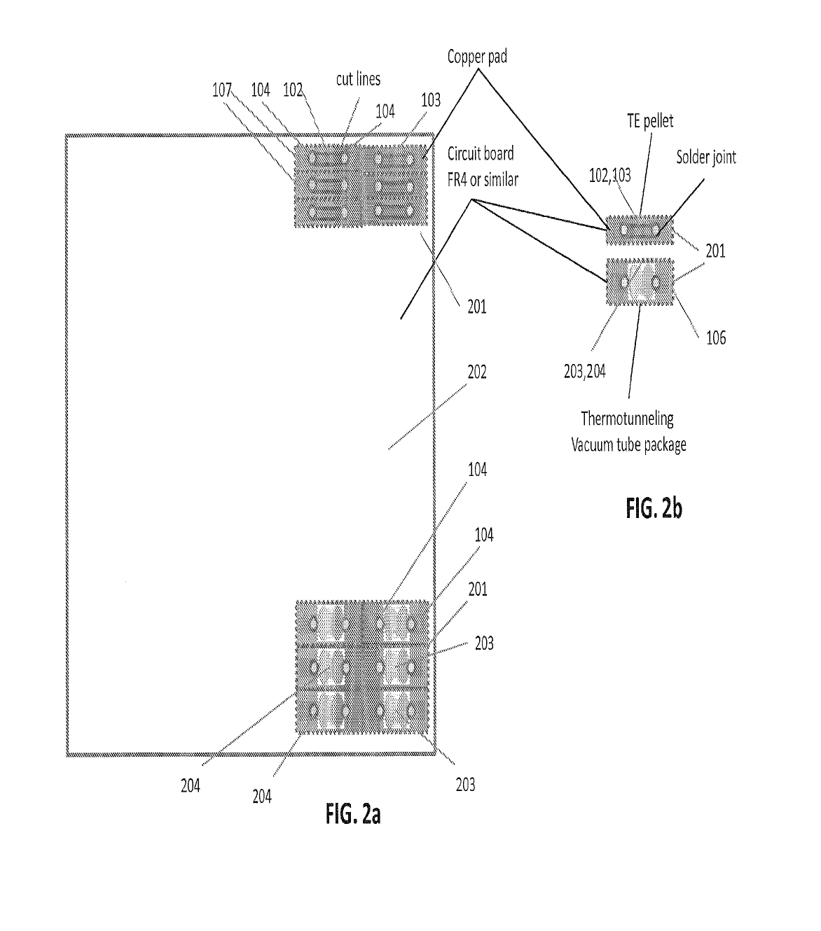

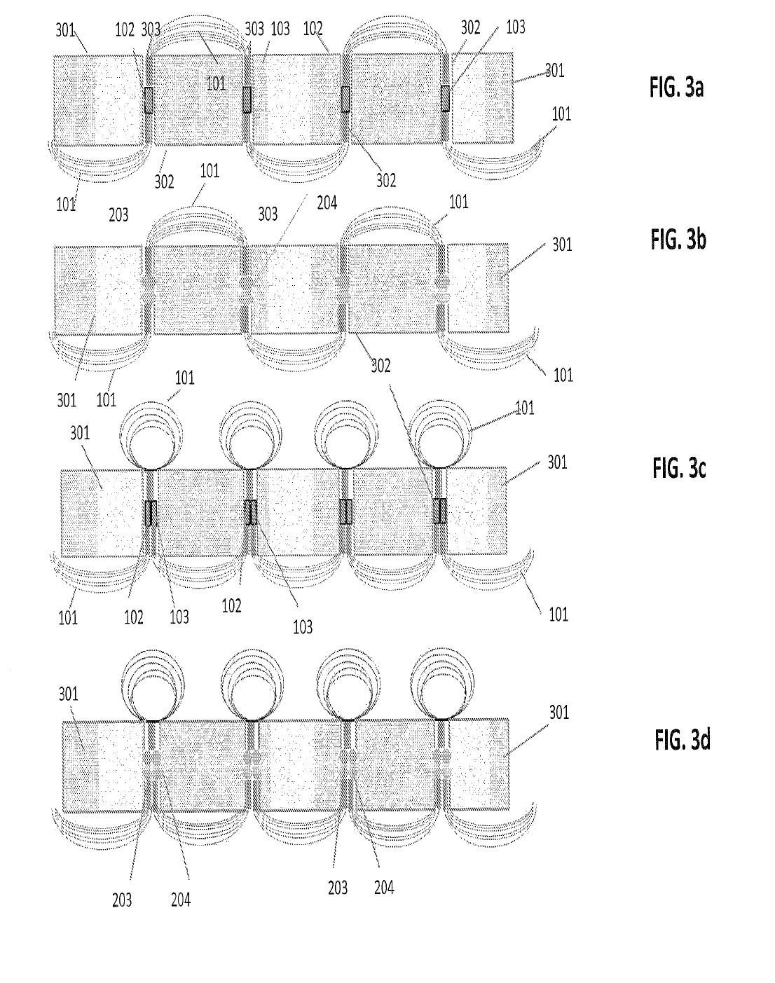

FIGS. 2a and 2b illustrate a method of assembling the thermoelectric elements on strain reliefs using a standard circuit board manufacturing process; FIG. 3a illustrates how the braid of FIG. 1a, with pellets, is woven on alternating sides of an insulating panel;

FIG. 3b illustrates how the braid of FIG. 1b, with thermo-tunneling tubes, is woven on to alternating sides of an insulating panel;

FIG. 3c illustrates how the braid of FIG. 1a, with pellets, is woven on to one side of an insulating panel;

FIG. 3d illustrates how the braid of FIG. 1b, with thermo-tunnelling tubes, is woven on one side of an insulating panel.

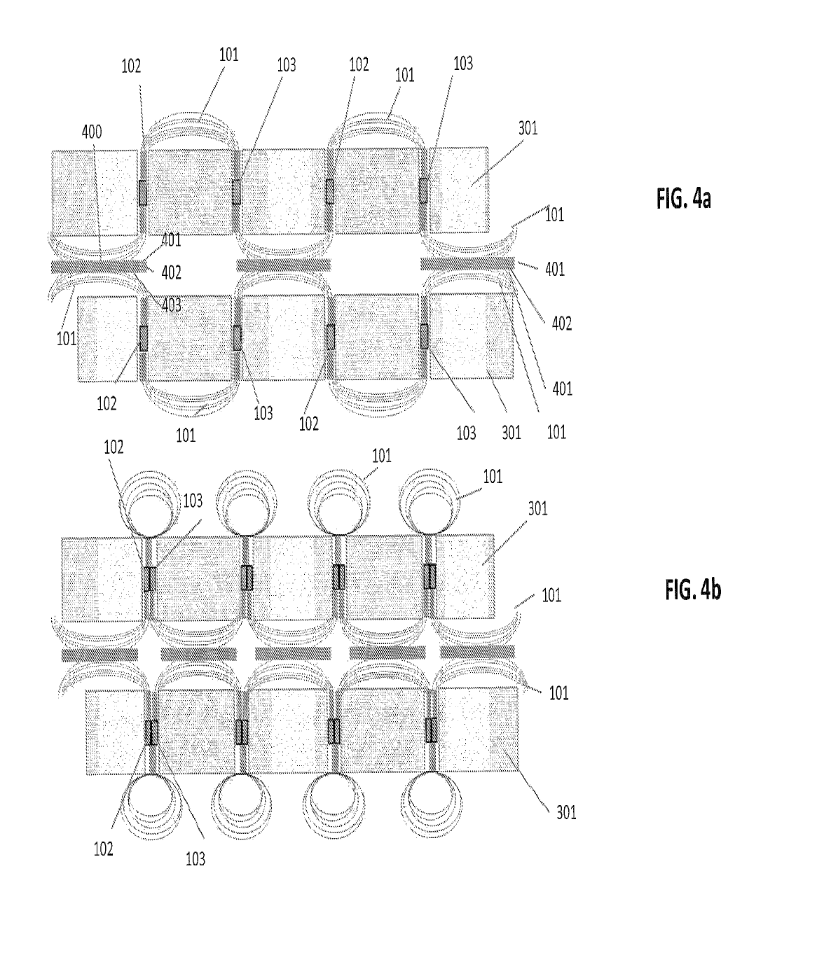

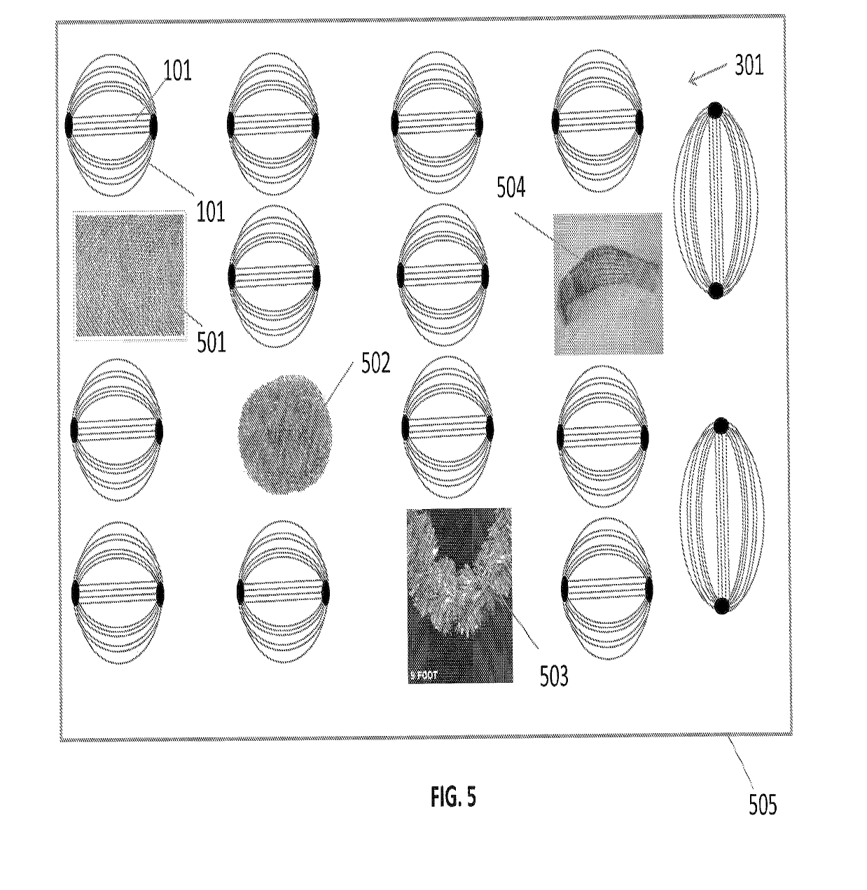

FIG. 4a illustrates how multiple layers of panels shown in FIG. 3a can be cascaded in order to more efficiently achieve a high temperature difference;

FIG. 4b illustrates how multiple channels of the panels of FIG. 3c can be cascaded in order to more efficiently achieve a high temperature difference;

FIG. 5 is a top plan view of a panel illustrating various examples of how multiple metal materials can serve as expandable heat sinks or heat absorbers;

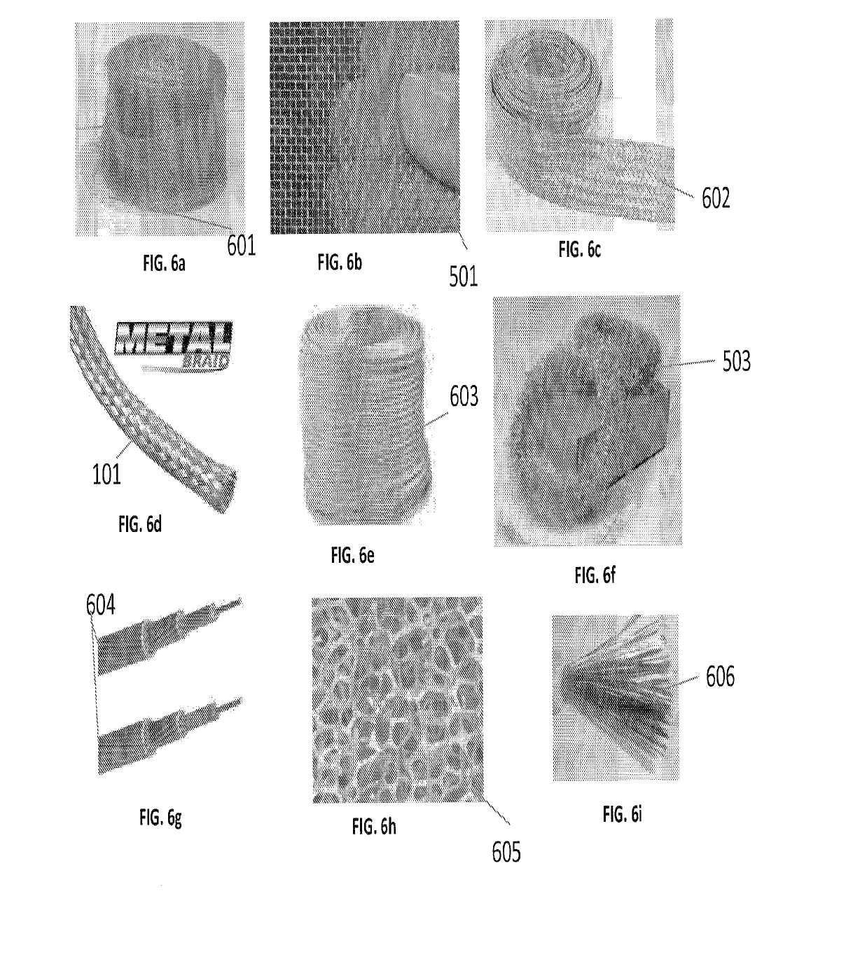

FIGS. 6a-6i illustrate various expandable metals which advantageously may be employed in the present invention including un-oriented copper mesh (FIG. 6a); oriented copper mesh (FIG. 6b); flat copper braid (FIG. 6c); tubular copper braid (FIG. 6d); copper rope (FIG. 6e); copper tinsel with wire center (FIG. 6f); oriented stranded copper (FIG. 6g); copper foam (FIG. 6h); and un-oriented stranded copper (FIG. 6i).

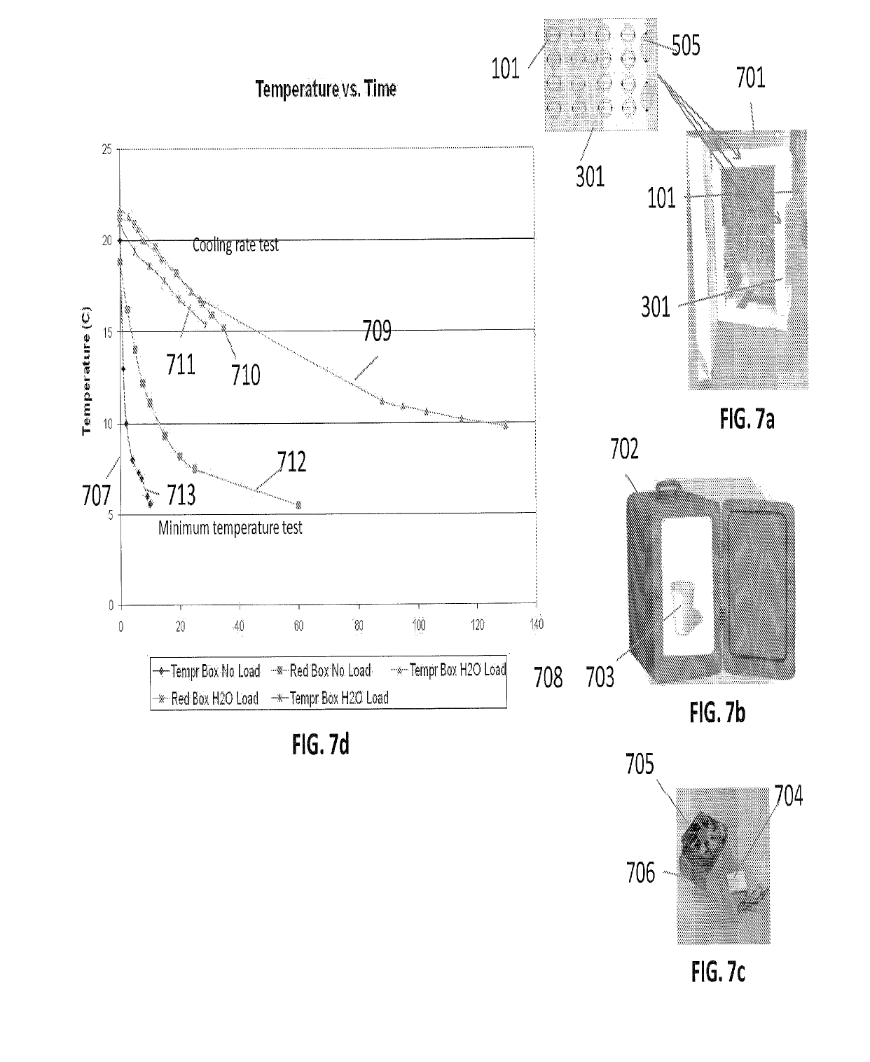

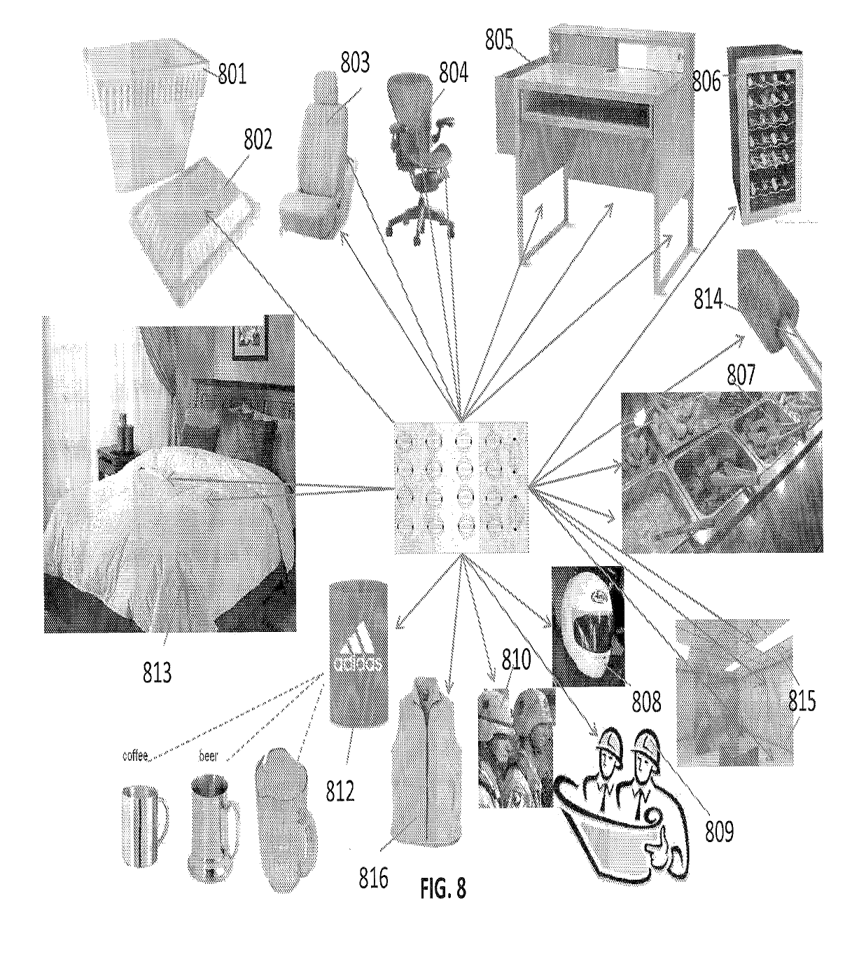

FIGS. 7a-c illustrated a thermoelectric cooler made in accordance with the present invention, and FIG. 7d plots time versus temperature comparing a thermoelectric cooler of the present invention with a prior art commercial cooler;

FIG. 8 illustrates, without limitation, many of the applications for the panel of FIG. 3 or FIG. 4 for heating and cooling functionality;

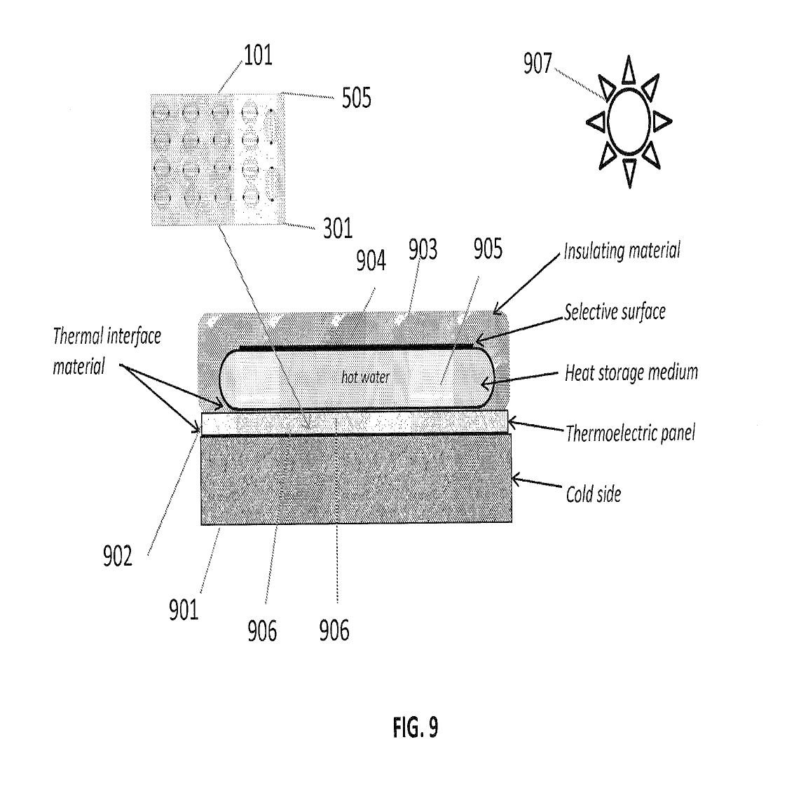

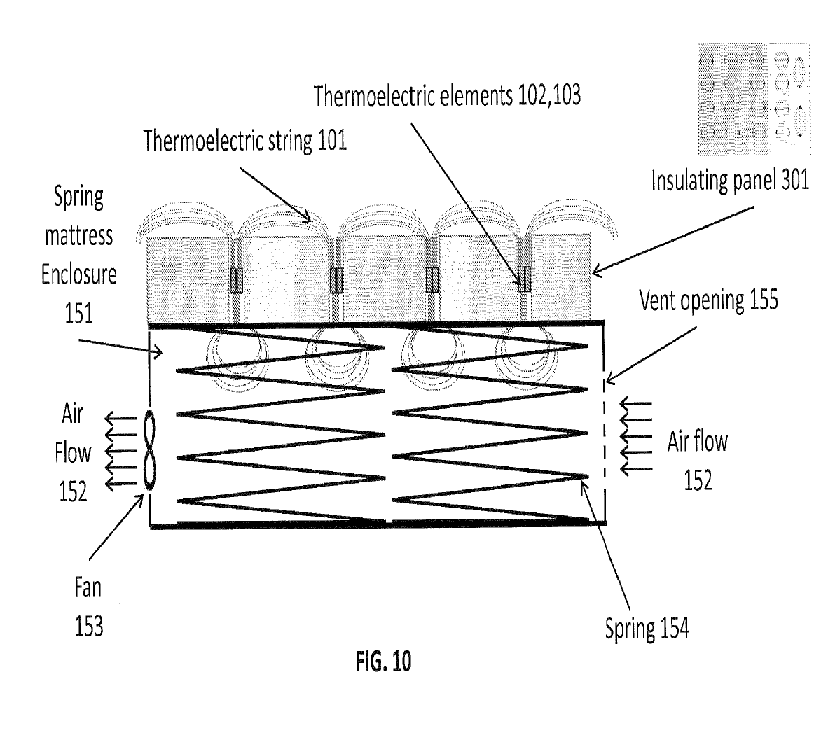

FIG. 9 illustrates one application for the panel of FIG. 3 or FIG. 4 for generating electricity from a heat storage medium heated by the sun;

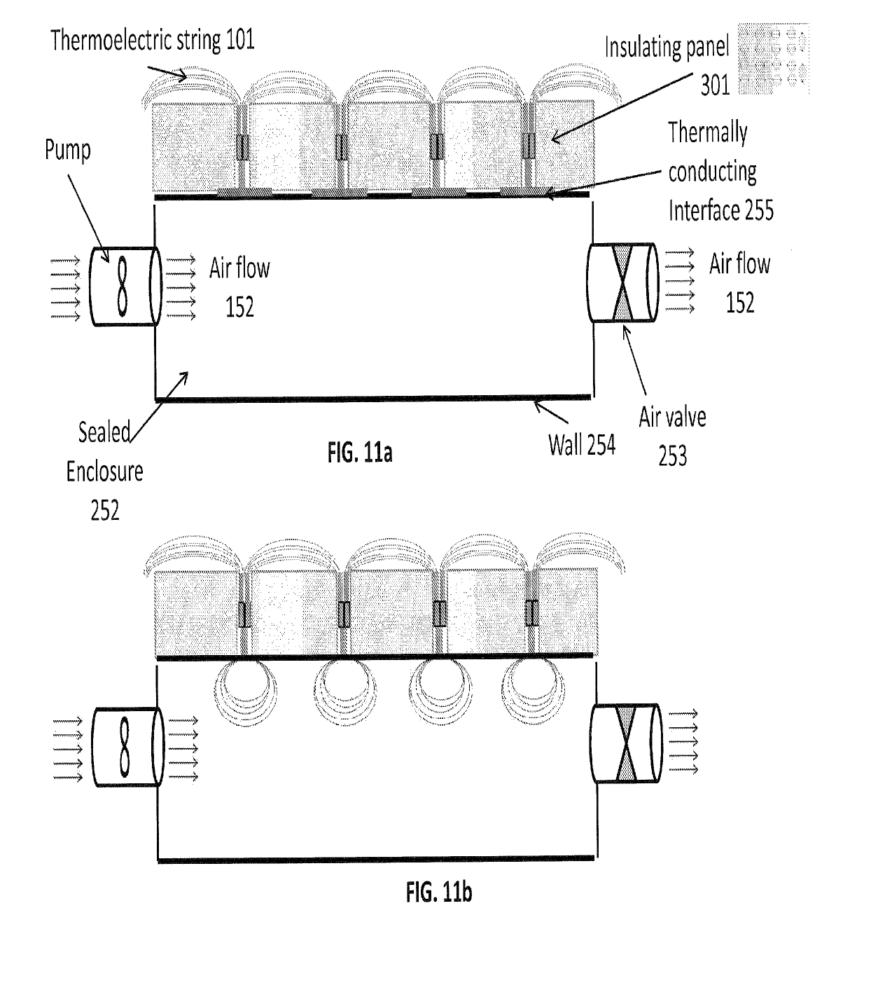

FIG. 10 shows the panel of FIG. 3 or FIG. 4 providing heating and cooling for the surface of a spring mattress;

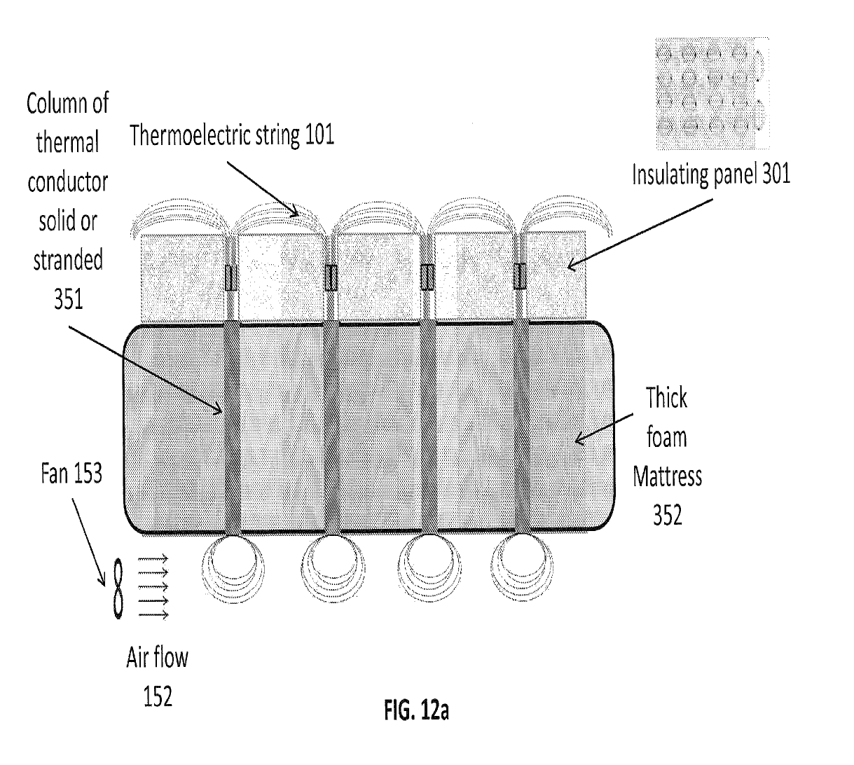

FIGS. 11a and 11b show the same panel providing heating and cooling for the surface of air mattresses;

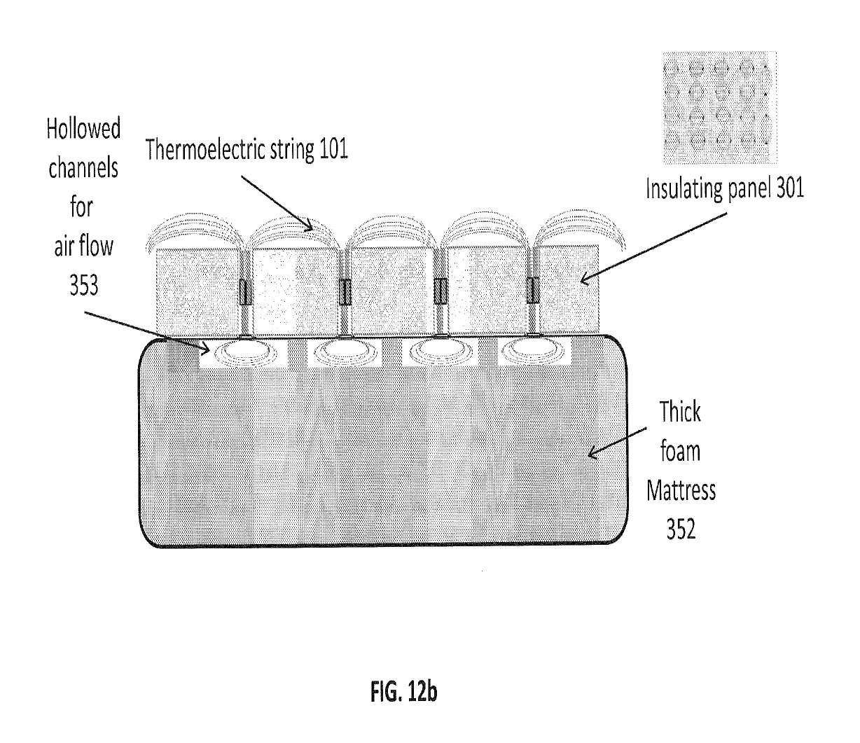

FIGS. 12a and 12b show the same panel providing heating and cooling for thick foam mattresses;

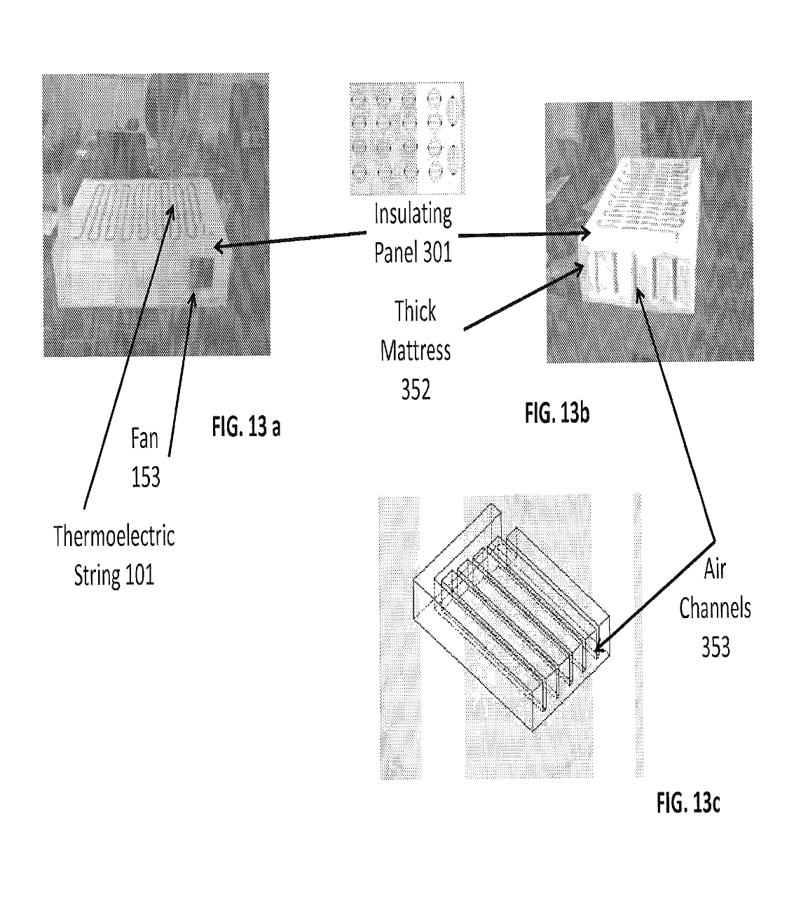

FIG. 13a is a perspective view, from the side showing a foam mattress made with thermoelectric panels of FIG. 12a;

FIG. 13b is a perspective view from the end of the mattress of FIG. 13a;

FIG. 13c shows the mattress of FIG. 13a with the thermoelectric panel removed;

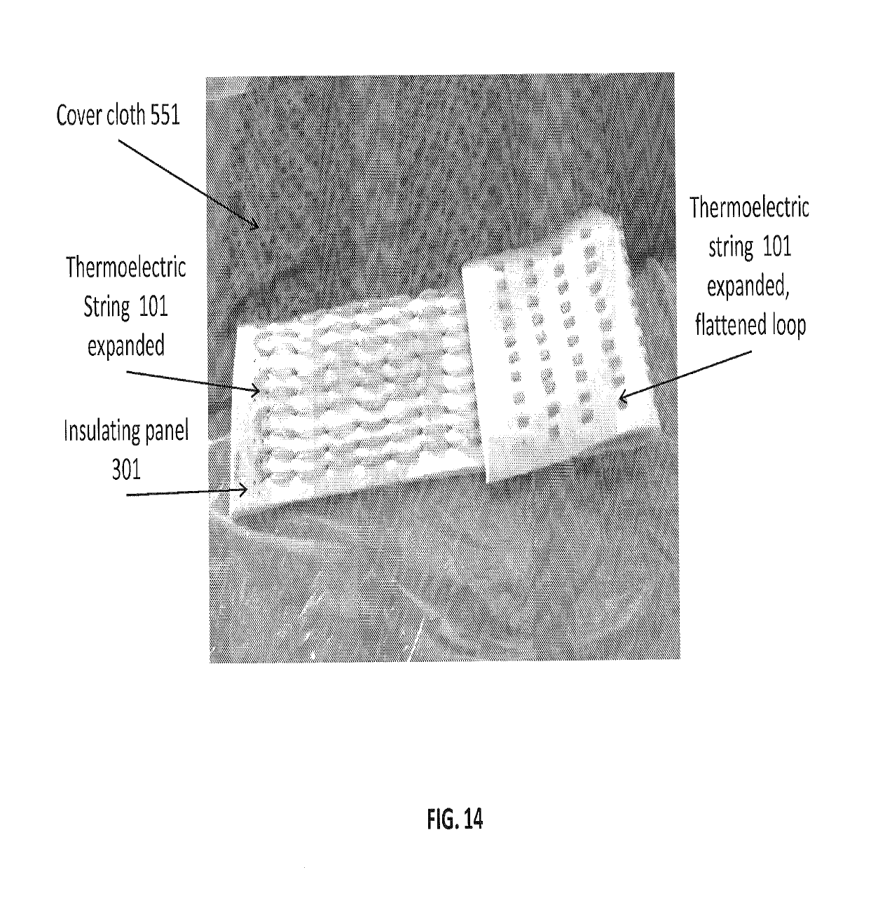

FIG. 14 shows a picture of a heated and cooled electric blanket built as described in FIG. 8;

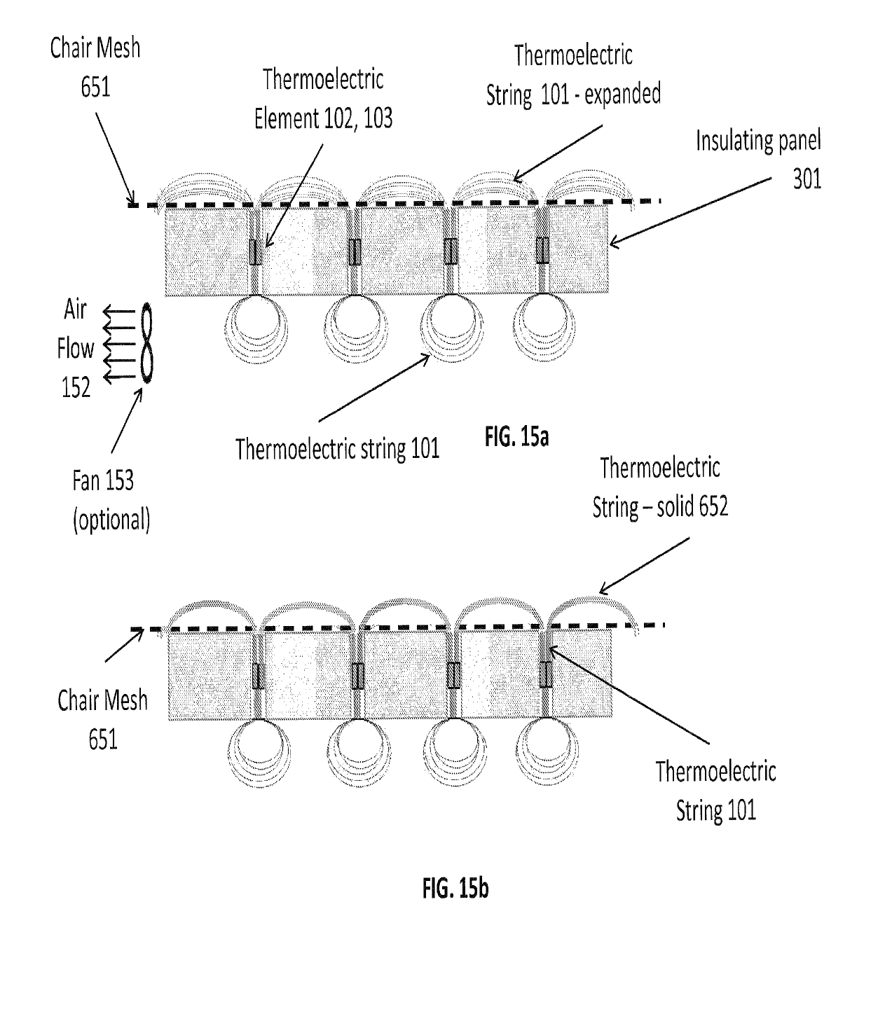

FIGS. 15a and 15b show integration of a thermoelectric panel of the present invention into a mesh-style office chair, FIG. 15a shows an expanded thermoelectric string, and FIG. 15b shows a solid thermoelectric string in accordance with the present invention.

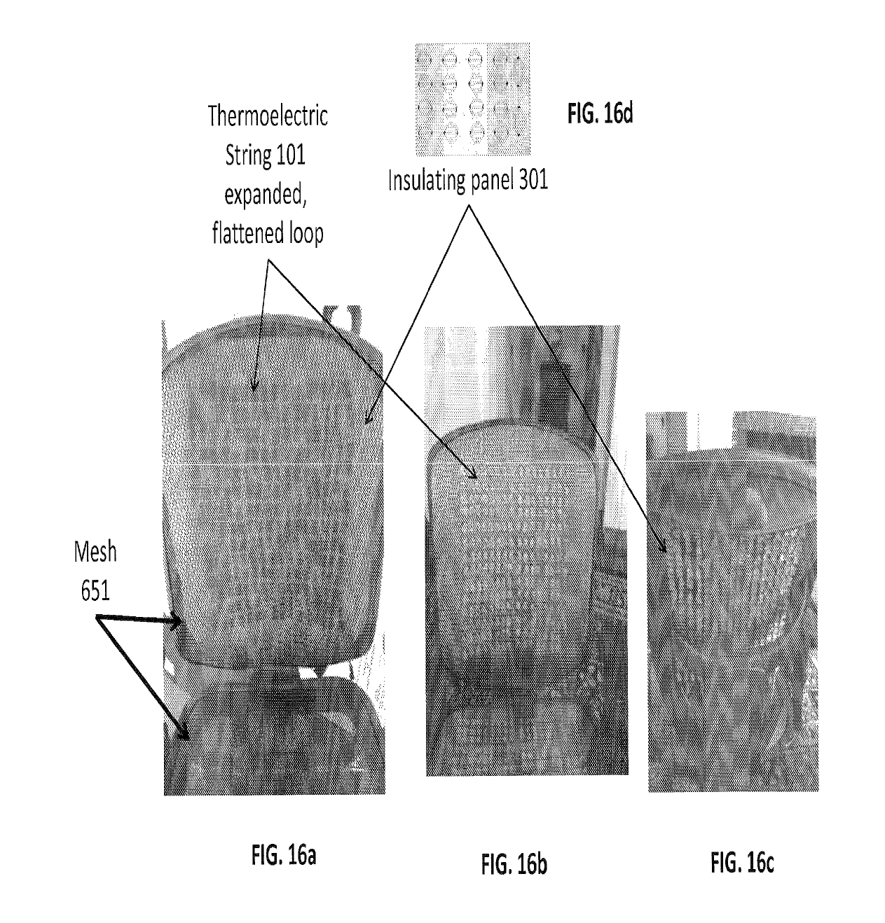

FIGS. 16a-16c illustrate incorporation of a thermoelectric panel as shown in FIG. 8 and FIGS. 15a/15b in a chair;

FIG. 16a shows the thermoelectric panel mounted behind the chair mesh;

FIG. 16b shows the thermoelectric string with portion of the string in front of the mesh;

FIG. 16c shows the thermoelectric string mounted on the back of the chair;

FIG. 16d shows a thermoelectric panel; and

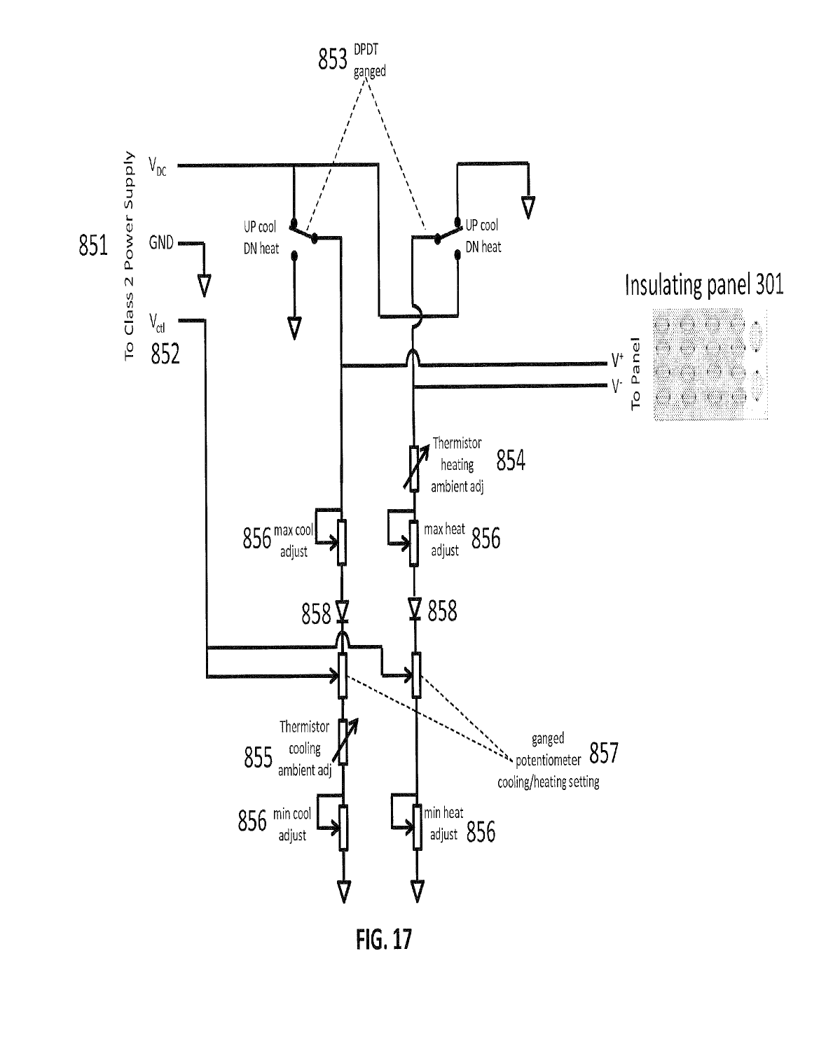

FIG. 17 shows an electronics circuit schematic diagram for a thermoelectric panel made in accordance with the present invention that includes a variable amount of heating and cooling.

A preferred embodiment of this invention includes a string containing alternating P-type 102 and N-Type 103 thermoelectric elements connected by lengths of braided or stranded wire 101 as shown in FIGS. 1a and 1b. The thermoelectric elements preferably comprise metals, although non-metallic conductors such as graphite and carbon may be used. In one embodiment, the alternating elements can be small crystals of, e.g. Bismuth Telluride (N-type) 103 and, e.g. Antimony Bismuth Telluride (P-type) 102, possibly plated with, e.g. Nickel and/or Tin on the ends to facilitate solder connections 104 or 105, or can be small thermo-tunneling vacuum tubes. Because the thermoelectric elements or tubes may be fragile, a “strain relief”, made of a stiff material 106 like FR4 combined with copper 107 and solder 104 or 105 bonds prevents a pulling force on the wire from breaking the elements or vacuum tubes. The aggregate diameter of the stranded or braided wire is designed to carry the desired electrical current with minimal resistance. In FIG. 1a, the strain relief is flat, facilitating its manufacture using standard circuit board manufacturing processes. In FIG. 1b, the strain relief is a tubular sleeve that is positioned over the elements 102 or 103 and over sufficient lengths of the wire 101. The design of FIG. 1b is beneficial if the thermoelectric element must be sealed and in order to save the cost and complexity of the separate circuit board manufacturing steps. Without limitation, the tubular strain relief 106 in FIG. 1b may be a woven fiberglass sleeve threaded over the thermoelectric element combined with an epoxy or glue. Once hardened, the combination of epoxy and the woven fiberglass is very stiff, as these same materials are used to produce the FR-4 circuit boards of FIG. 1a.

FIGS. 2a and 2b show how subassemblies of this thermoelectric string might be fabricated using standard circuit board assembly techniques and machinery. A large FR4 circuit board 202 is patterned with the copper pads 107 of the strain reliefs 106 of FIG. 1a. A packed arrangement is used to assemble the pellets 102 and 103 or tubes 203 and 204 onto the board. An assembly robot can place the thermoelectric elements or tubes and place solder paste 104 at the appropriate joints. The whole assembly is run through an oven to flow the solder and then cooled to harden the solder joints. Once assembly is completed, the strain relief assemblies are cut out along the cut lines 201 to leave the thermoelectric elements mounted on the strain relief 106.

The lower portion of FIG. 2a shows how the invention can also apply to the latest advanced thermo-tunneling devices. Such devices are more efficient, but require packaging in a vacuum tube. These small vacuum tubes can substitute for the thermoelectric elements 102 and 103 of FIGS. 1a and 1b and can also benefit greatly from the strain reliefs 106 of FIGS. 1a and 1b and 2a and 2b. Since a useful vacuum package must have a thin glass wall to minimize thermal conduction, it will also likely be very fragile.

The thermoelectric elements of FIGS. 1a and 1b alternate between N-type 103 and P-type 102 in order to move heat in the same direction while the current flows back and forth along the string woven into a panel 301 as shown in FIG. 3. One purpose of compacting the wire strands in the string of FIGS. 1a and 1b is to be able to route the string through small-diameter holes 302 in the panel. The hole diameter should be small to minimize thermal leakage that compromise the insulating capability of the panel material. Another purpose of compacting the wires near the elements is to minimize the area for heat to backflow from the hot side of the element to the cold side of the element. The string may be woven into the panel 301 in an alternating fashion as illustrated in FIG. 3a and FIG. 3b. Or, the N-type and P-type elements may be paired together to allow the string to be pushed though the holes 302 from one side as illustrated in FIG. 3c and FIG. 3d. The single sided approach in FIGS. 3c and 3d facilitates manufacture of the panel from one side rather than having to work with both sides as in FIGS. 3a and 3b.

Another embodiment is when the compacted portions 303 of the string within the panel holes of FIGS. 3a and 3b are replaced with solid cylinders made of copper or similar metal and these cylinders are attached to the thermoelectric element on one end and the expanded wire 101 on the other end. This approach would facilitate robotic placement of the cylinders and elements in the holes in an electronic assembly operation.

Yet another embodiment is to weave or assemble the string into a mold instead of the panel of FIGS. 3a-3d, then injection-mold the panel material into the mold. Upon removal of the mold, a similar configuration to FIGS. 3a-3d is obtained.

In the embodiment of FIGS. 3a-3d, the thermoelectric elements or tubes are spaced apart over a larger area vs. prior art modules, but the hot and cold sides are also separated by a length much longer than the elements. Since heat backflow conduction is proportional to area/length, scaling both simultaneously maintains a similar overall heat backflow as prior art thermoelectric modules. Since many desirable insulating panels like Styrofoam™, cloth, etc. have thermal conductivities comparable to air, the conduction ability of the invention's panel is comparable to that of the air cavity in prior art modules. In addition, the presence of the opaque panel blocks heat backflow from radiation almost entirely.

Once woven or placed, the exterior metal 101 in FIGS. 3a-3d is expanded, if necessary, on the hot and cold sides of the panel in order to maximize the exposure of the metal to air, which in turn maximizes its heat sinking or absorbing capability in either a natural or forced-air convection environment.

A key element of this invention over the prior art is re-optimizing the heat sinks for natural convection vs. the forced-air convection. With prior art forced-air convection systems, usually based on a fan, the forced air is moving in one direction only. Hence, the optimal heat sink is a metal plate for spreading the heat and linear metal “fins” for distributing the heat along the direction of the forced air. So, in prior-art forced air systems, the optimal heat sink maximizes the area touching air along the airflow, as represented by the parallel fins commonly used.

For a natural convection environment, the air flow velocity is much less than with a fan, but the air has the ability to move in all directions. Hence, the optimal heat sink for a natural convection environment is one that maximizes the area touching air in any direction.

In this preferred embodiment, re-optimizing the heat sink for natural convection brings about the following advantages: (1) better uniformity of the absorption of heat on the cold side and of the dissipation of heat on the hot side, (2) silent operation by eliminating the need for a fan, (3) much less total metal required, (4) more reliable because fans are prone to failure, (5) more efficient because the temperature change across the heat sink can be recovered to provide better additional cooling.

A typical prior-art thermoelectric module deployment has a heat sink with fins that are typically 2 mm thick. Because two surfaces of the fin are exposed to air, the total cross section perimeter of exposure is 4 mm for each thermoelectric element. In the preferred embodiment of this invention, the aggregate diameter d of the compacted wire is 1 mm. However, when the strands are spaced apart on the hot or cold side as shown in FIGS. 3a-3d, the total cross section perimeter exposed to air is now Nπ(d/N^{1/2}) where N is the number of strands and d is the aggregate diameter. As stranded wire is easily available with 100-400 strands, then total cross section exposed to air for the invention is 31.4-62.8 mm, more than seven times the exposed cross section for prior art devices. Because of this larger cross section of exposure, the heat dissipation and absorption capacity of the invention can be, depending on geometric parameters, sufficient to eliminate the need for a fan as well as a rigid heat sink and rely instead only on natural convection. In addition, the larger amount of area touching air by the use of strands reduces the total amount of metal required for heat dissipation, facilitating lightweight, soft, and wearable panels.

Furthermore, the number of stranded wires in FIGS. 3a-3d may be increased almost arbitrarily while the diameter of each strand is proportionately decreased. As discussed above, more strands leads to increased heat absorption and dissipation by a factor N^{1/2} with natural convection. Thinner strands also allows for the heat sink of the invention to be soft, lightweight, and flexible in contrast to rigid, hard, and heavy heat sinks of the prior art. Wire braid of tinned copper with 72-400 strands is typically used in the electronics industry, and such braid is designed to be expandable in order to serve as shielding of cables of varying diameter. Each strand in these braids is AWG 36 or about ˜100 microns in diameter. Another type of braid, wick-braided copper, is used to remove solder and its strands are even thinner, making possible a very soft device for dissipating heat and carrying electrical current in a thermoelectric panel when the strands are spread apart. Copper mesh is also readily available with even thinner strands of 44 AWG and spread out in 140 strands per inch when fully expanded.

Without limitation, the panel 301 in FIGS. 3a-3d may be Styrofoam™, natural cloth, synthetic cloth, natural sponge, synthetic sponge, polyurethane, fiberglass, foam glass, building insulation material, wood, paper, cotton, batting, pipe-wrapping insulation, ceiling tile material, memory foam, cushion material, or any other insulating material.

In some cases, it is desirable to have multi-stage thermoelectric cooling and heating. Higher temperature deltas are achievable. Prior art modules often are stacked together in a cascade configuration with 2 to 4 stages typically to achieve the very low temperatures needed for sensitive imaging cameras. The same multi-staging is possible with this invention and provides similar benefits, as illustrated in FIGS. 4a-4b. Here, two panels 301 are connected thermally in between by thermal connectors 400 that have high thermal conduction and electrical isolation. The thermal connectors may contain copper solder pads 401 and an electrically insulating layer like polyimide 402. In this configuration, the polyimide layer 402 is so thin that its thermal conduction is high. Without limitation, the electrical insulator could be FR-4, Kapton, Teflon, an insulated metal substrate circuit board, aluminum oxide or any other readily available material. The multi-stage configuration may be applied to the alternating weave as shown in FIG. 4a or to the single-sided weave as shown in FIG. 4b. The thermoelectric elements are shown as pellets 102 and 103 but could also be thermo-tunneling tubes 203 and 204 shown in FIGS. 2a-2b and 3a-3d.

FIG. 5 shows several different types of expandable metal conductors that may replace the braid 101 in FIGS. 1a and 3a and 3d, and 4a and 4b. Copper mesh is available in an oriented form 501 or un-oriented form 502 and either provides strands with high contact area to air. Metal tinsel 503 has a thick central wire which is convenient for moving electricity from one thermoelectric element to the other plus many branches of thin copper strands which are convenient for dissipating or absorbing heat to or from the air. Flat braid 504 is also available with or without solder joints on either end. A panel made with one or a combination of these expanded metals 505 becomes a fully functional thermoelectric panel.

FIGS. 6a-6i show even more possibilities for expanded or expandable metals, including another type of un-oriented copper mesh 601, copper strands weaved like rope 603, coaxially grouped strands 604, copper foam 605, or loose copper strands 606. For the metal screen or mesh, the metal may be compacted by rolling tightly or folding tightly in an accordion shape near the thermoelectric elements, and loosening the roll or the folds away from the thermoelectric elements.

The thermoelectric panels described can also be deployed for generating electricity from heat. When heat is applied to one side, a Seebeck voltage is generated that can be used for electrical power. The heat source can be a selective surface receiving sunlight, a road or highway surface, geothermal heat, engine heat, smokestack heat, body heat, waste heat, and many other possibilities.

### EXAMPLE 1

### A Thermoelectric Cooler Using Invention

FIGS. 7a-7c illustrate a thermoelectric cooler 701 using the invention. Four thermoelectric panels 505 were built using a string as shown in FIG. 1a with braid 101 lengths 7 and 11 cm for the cold and hot sides, respectively. The panels were 1-inch (2.54 cm) thick Styrofoam™ 301 with 3 mm diameter holes and a pellet spacing of 3 cm. A total of 256 pellets were inserted into the four populated panels. The four thermoelectric panels were combined with two plain Styrofoam™ panels to construct a small cooler. The cooler 701 in FIGS. 7a-7c did not contain a heat sink or a fan and was powered with 20 watts of electricity.

The cooler of FIGS. 7a-7c was compared with a prior art commercial cooler 702 that contains a prior art thermoelectric module 704 also with 256 pellets, a prior art heat sink 706, and a prior art fan 705. This commercial cooler was powered as designed with 40 watts of electricity.

FIG. 7d shows the data taken during an experiment to compare the invention cooler with the prior art commercial cooler. The two key measures of performance for such a cooler are (1) the rate of cool-down for a room-temperature cup of water 703 and (2) the minimum temperature reached by the air inside each cooler. The graph 707 in FIG. 7d plots the temperature on the Y-axis and the elapsed time in minutes on the X-axis.

The experiment revealed that the cooling-down rate for the cup of water, indicated by the slope of the line 709 and 711 for the invention, was comparable to the cooling-down rate of the prior art commercial cooler, indicated by the slope of 710. In addition, the minimum temperature of the air inside the box reached 5.5 degrees C. for both the invention cooler as indicated by line 713 and for the prior art cooler 712.

The data in FIG. 7d indicates that the invention performs as well as the prior art commercial cooler in cooling. However, the invention only required 20 watts of power vs. 40 watts for the prior art commercial cooler. Hence, the invention achieved the comparable performance with significantly greater efficiency. The greater efficiency is due to the following: (1) not requiring the electrical power for a fan, (2) recovery of much of the temperature drop across the heat sink, and (3) better distribution of the cooling over the walls of the container.

The thermoelectric panels of the invention illustrated in FIGS. 3a-3d and 4a and 4b are generalized insulating panels with the ability to cool or heat one side relative to the other. These generalized panels may be manufactured using a similar process and with similar machines and then deployed in a plurality of applications. Without exception, some of these applications are illustrated in FIG. 8.

In order to save overall energy or achieve greater individual comfort in cooling or heating the human body, one advantageous technique is to allow for local heating or cooling relative the environment. For example, the thermoelectric panel of the present invention may be placed around the cavity under a desk 805 as illustrated in FIG. 8 to provide local comfort for an office worker with significant energy savings. Or, the panel could be placed in an office chair 804 in the seat bottom or the seat back or both. In a vehicle, the panels may be placed in the seat bottom or seat back of a car seat 803. For sleeping, these panels may be placed in an electric blanket 813 combined with a thermostatic controller to maintain a desired under-blanket sleep temperature. The control electronics for the blanket can automatically switch the electrical current in the proper direction when cooling is needed to achieve the set temperature or when heating is needed. Without limitation, such thermostatic control can be applied to any of the applications of the invention including all of those illustrated in FIG. 8.

For individuals that must wear helmets, the body heat confined inside the helmet can be uncomfortable. Or, the helmet may not provide sufficient warmth when worn in cold environments that require head protection. The thermoelectric panel of the present invention may be molded into the proper shape to add cooling and heating capability to helmets of all types, including motorcycle or bicycle 808, military 810, or hard hats 809 for construction sites.

Similarly, the invention panel may be shaped and used to make clothing like vests 816 or, without limitation, other types of clothing such as coats, pants, pant legs, and shirts.

The thermoelectric panel of the present invention also can be used to cool food and drinks or other objects. These panels can be deployed as the wall, door, back, or top of a wine chiller 806 or a camping cooler 801 and 802. Because the panel and string can be flexible 812 in FIG. 8, it can be wrapped around shaped objects like water pitchers, beer or other mug or bottles, coffee drinks, milk or cream bottles or cartons, etc.

The thermoelectric panel of the present invention also may be deployed to heat or cool buffet trays 807 shown in FIG. 8 for self-serve restaurants, cafeterias, or catering services. The prior art uses ice to cool the trays and boiling water to heat them. The supply of ice and hot water must be maintained and the reservoir under the trays must be replenished periodically. The present invention provides benefits over the prior art by heating or cooling the trays electrically and not requiring cold and hot supplies.

The thermoelectric panel of the present invention also may be deployed in residences and buildings, A portion of a wall or window or floor 815 may be replaced by the panel of the present invention and provide heating or cooling for room. The ceiling tiles 815 in buildings also may be replaced by the panels of the present invention to provide heating and cooling for the space underneath the ceiling. The panel of the present invention also may be employed in combination with central compressor-based air conditioning systems to eliminate the need for forced air that can carry germs and smells from one room to another. In this case, the panels of the present invention would be mounted along plenums with the hot side facing into the plenum. The cool air from the compressor-based HVAC system would carry the heat away from the hot side while the cold side of the panel removes heat from the room. In this case, the room is cooled without forced air.

In another aspect, the invention, provides renewable electrical power from the sun's radiation in well-suited climates. A second purpose is to continue providing energy when the sun is not shining and all night long. A third purpose is to improve the land utilization as measured in Kwatts/acre to many times higher than a wind turbine farm. A fourth purpose is to provide peak power capacity at a time of day that better matches the typical peak demand time for electricity. A fifth purpose of this invention is to use inert and non-toxic materials to store the energy of the sun in the form of heat. A sixth purpose is to provide these capabilities at a cost per watt that is a fraction of the cost (including fuel costs) of a traditional power plant and an even smaller fraction of the cost per watt of a PV or wind turbine plant (including battery storage costs). As discussed below, the invention demonstrates better performance over prior art implementations that do not have energy storage such as U.S. Pat. No. 3,088,989, by additionally distributing the thermoelectric elements to match the heat distribution from un-concentrated sunlight and remove the need for metal heat spreaders.

An embodiment of the invention is illustrated in FIG. 9. An insulating material 903 that is largely transparent to the sun's radiation surrounds heat storage medium 905. The insulating material 903 also prevents the heat from escaping when the sun 907 is not shining. The insulating material may be, without limitation, bubble wrap, glass or Plexiglas sealing in air or air pockets, or any of the materials used for solar covers for swimming pools. A selective surface layer or coating 904 of the heat storage medium is designed to absorb radiation from the sun and prevent radiative re-emission of absorbed heat. This selective surface layer or coating 904 may be constructed, without limitation, from, e.g. an oxide of copper, aluminum, or iron, from carbon, steel or a combination or alloy of these, black paint, or similar materials used in solar ovens, solar camping showers, or solar rooftop water heaters. The heat storage medium 905 contains a large volume of a material with a high heat capacity. This material could be water, which has a volumetric heat capacity of 4.2 joules/cm³/° C. or could be scrap iron which has a heat capacity slightly less than water. The selective surface 904 and the heat storage medium 905 are in good thermal contact. This contact possibly employs a thermal interface material 906 there between that has high thermal conductivity, the ability to mate the surfaces, and the ability to spread the heat. The heat storage medium 905 is thermally connected to the hot side of a distributed thermoelectric panel 902, again possibly employing a thermal interface material 906. The distributed thermoelectric panel 902 is an insulating panel with thermoelectric elements inside, as described in FIGS. 2a and 2b and FIGS. 3a-3d. The cold side of the thermoelectric panel 902 is thermally connected to ground 901 or floating on a body of water such as an ocean, lake, or pool.

Without limitation, the power generator illustrated in FIG. 9 could generate power only when the sun 907 is shining, eliminating the need for storage medium 905. In this case the selective surface 904 would be adjacent to the thermoelectric panel 902, possibly with a thermal interface material 906 there between.

Again without limitation, the power generator of FIG. 9 could employ a heat source other than sunlight. The water in the storage medium 905 could flow from an active geothermal source, or be heated waste water from a power plant or factory. If the thermoelectric panel 902 were built in the flexible configuration described earlier, then it could be wrapped around pipes carrying hot water or hot gases and generate electricity as illustrated in FIG. 8, item 814.

### EXAMPLE 2

### Solar Power Storage and Electricity Generation

An example power generator in accordance with FIG. 9 will now be described that is competitive with other power generators such as wind turbines and photovoltaic panels. The heat storage medium 905 is 2 m×2 m×0.3 m and is assumed to reach a peak temperature of 100° C. This temperature does not exceed the boiling point of water, and is a temperature easily reached by insulated solar ovens used to cook food. The cold side 901 temperature is assumed to be room temperature or 20° C. The delta temperature ΔT across the thermoelectric panel 902 is then 80° C. and the average temperature is 60° C. The heat storage medium at a temperature elevated by 80° C. relative to ambient stores 4.0 E+8 joules or 112 Kwatt-hours if the heat capacity of water at 4.2 joules/cm³° C. is assumed.

The insulating material 903 dimensions are 2 m×2 m×0.05 m, and so the thermal loss through the thickness of the insulator at the ΔT of 80° C. is 147 watts if a typical thermal conductivity of air-pocket insulators of 0.023 watts/m° C. is assumed.

Thermoelectric elements are readily available with an electrical resistance r of 0.005 ohm, thermal conductance K of 0.009 watts/° C., and Seebeck coefficient S of 300 μV/° C. These values indicate a thermoelectric performance ZT=S²T/rK at the average temperature of 60° C. (333K) of 0.60, which is well within the performance claimed by most manufacturers.

The distributed thermoelectric panel 902 is 2 m×2 m×0.05 m, and it contains 1333 thermoelectric elements. The elements are spaced apart by 5.5 cm in each lateral direction. The total thermal loss through the elements is 960 watts (1333ΔTK). The total voltage V generated by the elements connected in series is 1333SΔT or 32 volts. The total resistance of the elements, all connected in series, is R=1333r=6.7 ohm. Assuming a matched load of 6.7 ohm, then the current flow I is V/2R or 2.4 amps. Hence, a total of 38.4 watts (0.5VI) of power is available to the load by this example embodiment.

The sun's 907 radiation is known to be about 1000 watts/m², which indicates that 4000 watts reaches the selective surface 904. After subtracting the loss through the thermoelectric elements and through the insulating material, 2893 watts (4000−960−147) is absorbed as heat in the heat storage medium 905. Because 4000 watts are entering the medium for 8 hours of the day and 1145.4 watts (960+147+38.4) are leaving the medium for 24 hours of the day, more energy (net 4.52 Kwatt hours per day) is entering per day than is leaving, allowing for this embodiment to reach and maintain a maximum temperature. The heat builds up in the heat storage medium until it reaches its heat capacity of 112 Kwatt hours. The time required to reach the maximum temperature is about 25 days (112 Kwatt hours/4.52 Kwatt hours per day).

While this embodiment is less than 1% efficient on an instantaneous basis (38.4 watts generates/4000 watts available from the sun), which is a conservative expectation for a thermoelectric generator at these temperatures, making use of the heat storage allows the thermoelectric device to be about 3% efficient on a daily average basis.

A feature and advantage of this embodiment is that it reaches its maximum temperature in the mid-afternoon hours as heat builds up in the heat storage medium 905. Hence, the time of maximum power output of this embodiment better matches the time of peak demand for electricity. Photovoltaic panels have their maximum output at noon, which is two hours earlier than the peak demand. The daily maximum output of wind turbines is unpredictable.

With this embodiment, 38.4 watts of electrical power generated in a 2 m×2 m area corresponds to 38 Kwatts per acre, which compares very favorably to wind turbines which average about 4 Kwatts per acre.

Another feature and advantage of the present invention is that the storage medium, water, of this embodiment, is essentially free as the water does not even need to be fresh water. Storing energy as heat is much less costly than storing energy as electricity, and it may be stored without the toxic chemicals found in batteries.

### EXAMPLE 3

### A Distributed Thermoelectric Mattress

FIG. 10 illustrates how the thermoelectric panel of FIG. 3c can be used to heat or cool the surface of a mattress with springs. The braided or stranded wire of the thermoelectric string 101 extends into the cavity of the mattress enclosure 151. A fan 153 is used to move heat away from or toward these wires, depending on whether mattress surface is being heated or cooled. Because the heat is highly distributed by the invention, the fan 153 can have much lower revolutions per second to keep down noise and power consumption. In some cases, a fan may not be needed at all if the cavity of the mattress is well ventilated by other means. The air flow 152 generated by fan 153 sees little resistance from the presence of the springs 154. A vent 155 allows the air from fan 153 to escape to the environment.

FIGS. 11a and 11b illustrates a similar concept for an air mattress. The air pressure in the mattress might be controllable to provide varying amounts of firmness or might be fixed. A pump 251 is run continuously to remove or insert heat again depending on whether the mattress surface is being cooled or heated. In FIG. 11a, a thermal connection is made through the wall 254 of the air mattress by a thermally conducting interface 255. In FIG. 11b, the braided or stranded wire extends through holes in the wall 254 of the air mattress in order to make contact with the convective air flow 152 from pump 251.

FIGS. 12a and 12b illustrates a similar concept for a thick foam mattress 352. In FIG. 12a, thermally conductive columns 351 are used to thermally connect down through the thickness of the mattress to underneath the bed where convective air flow exists. A fan 153, if necessary, can supplement the natural convection. FIG. 11b employs hollow channels 353 in the foam mattress 352 to provide a convective path for air flow. These hollow channels may be lined with soft or hard pipes to restore the rigidity lost by the hollowed areas. A fan, not shown, if needed, is used to move convective air across the stranded or braided wire. Again, the fan can be very low speed because the heat is already highly distributed by the invention. Without limitation, the top portion of the mattress arrangement in FIG. 12b could be a topper for any mattress, thereby providing heating or cooling to that mattress without requiring modification to the mattress. Similarly, smaller sections of the arrangement in FIG. 12b could be deployed as seat cushions or seat back cushions to bring heating or cooling to any chair without requiring modifications to the chair.

FIGS. 13a-13c illustrate a similar concept for a thick foam mattress 352 in which air channels 353 are cut out of the foam. FIG. 13c shows a drawing of a thick foam mattress with the air channels 353 cut out of the foam 352. The channels 353 running the length of the mattress are all connected to a lateral channel that provides air to all of them. The thickness and depth of the channels can be designed to equalize the air flow in each channel appropriately. FIGS. 13a and 13h show two pictures taken at different angles of a prototype mattress built in accordance with drawing 13c. A thermoelectric panel 301 is placed on top of the mattress with the hollowed channels with the braided or stranded wire exposed to the convective airflow from the fan 153 to the ends of the channels 353.

### EXAMPLE 4

### A Distributed Thermoelectric Blanket

FIG. 14 shows a picture of the invention thermoelectric panel deployed as an electric blanket that heats and cools. The panel insulating material 301 is soft and light memory foam, but without limitation could be batting or other types of foam. The braided wires of the thermoelectric string 101 are shown on each side. A cover cloth 551 is used to cover the appearance and the feeling of the braided wire. This cover cloth needs to transmit heat effectively and hence may be comprised of a material with low thermal conductivity but very porous such as cotton, linen, or polyester, or be comprised of a material with high thermal conductivity but not very porous such as carbon impregnated films, or be comprised of a phase change material that moves heat through the changing of a phase from solid to liquid or from liquid to gas. Phase change fabrics such as Outlast are readily available for this purpose. Note how the thermoelectric effect in contact with one side of the phase change material allows it to be continually effective with continuous phase change cycles taking place over time vs. the single cycle of the material without the thermoelectric effect. Without limitation, this phase change material may be combined with any deployment of the distributed thermoelectric panel including all those illustrated in FIG. 8.

### EXAMPLE 5

### A Distributed Thermoelectric Chair

FIGS. 15a and 15b shows how the invention thermoelectric panel may be integrated with a mesh-style office chair. In these types of chairs, the mesh 651 supports the load and the distribution of pressure for the seated person. The intention of FIGS. 15a and 15b is to illustrate one embodiment of the thermoelectric panel in which heating or cooling is added to the chair's function without changing the structural or comfort properties of the original chair, Another objective is to have the braided or stranded wire of the expanded thermoelectric string 101 as close to the skin or clothing as possible in order to achieve a good thermal connection. For this reason, the wires are brought through the mesh 651 in their original compacted form, and then the wires are expanded on the side of the mesh 651 that contacts the skin or clothing. Without limitation, the wires could provide heating or cooling without being brought through the mesh, or the mesh could be made from a high thermal conductivity material, or the mesh could be a phase change material. If the wires of FIGS. 15a and 15b are in good contact with the skin, then heat may be conducted with a solid wire 652 as shown in FIG. 15b instead of stranded or braided wire shown in FIG. 15a. Also, if the desire is to insulate the wire to prevent shorting, then magnet wire or Litz wire can be used in place of un-insulated wire.

FIGS. 16a-16c shows pictures of a mesh style office chair that was built according to FIGS. 15a and 15b FIG. 16a shows a chair in which the braided wire panel insulating material 301 (FIG. 16d) of the thermoelectric string 101 is behind the mesh of the back of the chair. Without limitation, the same technique could be used to heat and cool the seat. FIG. 16b shows another chair in which the braided wire of the thermoelectric string 101 is brought through the mesh 651 to be in better contact with the skin. FIG. 16c shows the braid of the thermoelectric string 101 on the back side of the chair fully expanded with the braids exposed to open air for maximum effect of natural convection.

### EXAMPLE 6

### Thermoelectric Panel with Electronic Control

FIG. 17 shows a schematic of a control circuit that may be used to power and control the panel for all of the aforementioned applications of this invention. Power supplies 851 with variable voltage output are readily available in the computer industry such that one supply can be configured to power multiple laptop computers. These universal power supplies are available from IGO and other manufacturers, and they have an output with three wires: two wires supply the power and a third wire 852 senses a voltage level that determines the voltage output. When used in laptop computers, the desired control voltage is determined by a “tip” that sets the control voltage. In the implementation of FIG. 17, such a universal power supply is used to allow the user of the thermoelectric panel 301 to set a desired amount of heating or cooling.

The DPDT switch 853 in FIG. 17 sets the polarity of the current flow in the panel, hence allowing the user to select heating or cooling. The middle position of the DPDT switch 853 provides no connection and hence is used for the off position. The ganged potentiometers 857 determine the control voltage sent back to the universal power supply 851 and hence allow the user to set how much heating or cooling is provided by the panel. The presence of thermistor 855 raises the control voltage and hence increases cooling when the ambient temperature rises, and equivalently lowers this voltage to decrease cooling when the ambient temperature drops. The presence of thermistor 856 increases the control voltage and hence increases heating when the ambient temperature drops, and equivalently decreases the control voltage and decreases heating when the ambient temperature rises. Trimming potentiometers 856 set the minimum cooling, maximum cooling, minimum heating, and maximum heating that the panel 301 is allowed to generate. The intent is for these trimming potentiometers to be set at the factory to safe or otherwise desired levels. Diodes 858 ensure that only one of outputs of the ganged potentiometers 857 is able to set the control voltage 852.

Various changes may be made in the above, without degrading from the spirit and scope of the present invention.

1-25. (canceled)

26. A thermoelectric device comprising a plurality of strings of thermoelectric elements connected by conductors, wherein the conductors are compacted near the elements and are expanded away from the elements, and the string of elements are incorporated into panels that are stacked together in ascending or descending thermally order to achieve larger temperature differences.

27. The thermoelectric device of claim 26, wherein the plurality is a whole number equal to 2, 3, or 4.

28. The thermoelectric device of claim 26, wherein a plurality of string and panel assemblies are connected together and electrically isolated on a thermally conducting board or group of boards, preferably a circuit board or group of circuit boards.

29. The thermoelectric device of claim 26, wherein a plurality of string and panel assemblies are connected together and electrically isolated on thermally conducting boards by an electrical isolation material selected from the group consisting of FR4, Kapton and a polyimide.

30. The thermoelectric device of claim 26, wherein a plurality of string and panel assemblies are connected together and electrically isolated on thermally conducting boards by an electrical isolation material which is thin or contains a metal substrate with thin isolation layers to permit high thermal conduction, and wherein the thin electrical isolation material preferably is Kapton, a polyimide or an oxide of a metal substrate, and has a thickness of 10 to 40 microns.

31. The thermoelectric device of claim 26, further containing copper or other metallic pads to facilitate soldering of the expanded metal outside the stacked panels on either side of the board or boards.

32. The thermoelectric device of claim 26, further including strain relief for mounting and protecting the thermoelectric elements, wherein (i) the strain relief preferably is cut from or assembled from circuit board substrate material, and wherein the circuit board substrate material preferably is selected from the group consisting of a polyimide, Kapton, polyester, nylon, FR-4, epoxy, glue, and fiberglass or fiberglass cloth adjacent to or surrounding the thermoelectric elements and a portion of the compacted conductor; or (ii) wherein the strain relief comprises copper or other metallic pads for solder-attaching the compacted metal to the strain relief and to the thermoelectric element.

33. A method for forming a thermoelectric device as claimed in claim 26, wherein the thermoelectric elements are woven in and out of holes in an insulating panel, wherein portions of the metal within the holes in the panel are mostly compacted and portions outside the holes in the panel are mostly expanded, which comprises weaving strings of thermoelectric elements in a mold, injecting a settable panel material into the mold, allowing the panel material to set, and removing the mold.

34. A mattress comprising the thermoelectric device comprising a plurality of thermoelectric elements wherein the thermoelectric elements are woven in and out of holes in an insulating panel wherein portions of the metal within the holes in the panel are mostly compacted and portions outside the holes in the panel are mostly expanded, or pairs of thermoelectric elements having metal therebetween are pushed through a hole from one side of an insulating panel exposing a loop of expanded or expandable metal on the other side and retaining the elements within the panel, mounted on top of the mattress, wherein
(a) the mattress is a spring mattress, and a portion of the conductor is exposed in the cavity containing the springs and forced or natural convection of air is available in said cavity; or
(b) the mattress is an air mattress and the thermoelectric device is mounted on top of the air mattress, and includes a thermal connection of the conductor on one side of the device into the cavity containing the air and movement of the air is available in said cavity; or
(c) the mattress is a foam mattress and the thermoelectric device is mounted on top of the thick foam mattress in which a portion of the conductor extends into hollowed channels that provide natural or forced convection of air.

35. The mattress of claim 34 used on top of another mattress or sofa or couch or seat bottom or seat back as an accessory.

36. The mattress of claim 34 in which the hollowed channels also contain pipes or tubes for additional support.

37. The mattress of claim 34, including a fan or pump to provide forced convection of air.

38. The mattress of claim 35, including a fan or pump to provide forced convection of air.

39. The mattress of claim 36, including a fan or pump to provide forced convection of air.

40. The thermoelectric device comprising a plurality of thermoelectric elements wherein the thermoelectric elements are woven in and out of holes in an insulating panel wherein portions of the metal within the holes in the panel are mostly compacted and portions outside the holes in the panel are mostly expanded, or pairs of thermoelectric elements having metal therebetween are pushed through a hole from one side of an insulating panel exposing a loop of expanded or expandable metal on the other side and retaining the elements within the panel, mounted on the seat bottom or seat back or both of a chair, sofa, ottoman, wheelchair, pillow, or couch, and wherein the thermoelectric device preferably is mounted behind or underneath the existing support mesh in the back or bottom, and wherein a portion of the conductor of the thermoelectric device preferably protrudes through the mesh to achieve better contact with the skin or clothing.

41. A mattress, furniture, blanket, pillow or clothing comprising a string of thermoelectric elements connected by conductors, wherein the conductors are compacted near the elements and are expanded away from the elements, including a cover cloth over the conductor on the side of the thermoelectric device that contacts the skin or clothing.

42. The mattress, furniture, blanket, pillow or clothing of claim 41, wherein the cover cloth is comprised of natural or synthetic fabric that is thin and porous and allows air flow, or is comprised of a fabric, film, or mesh that is designed to have high thermal conductivity, or is comprised of a material that changes its phase when in contact with human or animal skin thereby moving or removing heat.

43. Clothing of claim 41, in the form of a hat or helmet.

44. A thermoelectric device comprising a plurality of thermoelectric elements wherein the thermoelectric elements are woven in and out of holes in an insulating panel wherein portions of the metal within the holes in the panel are mostly compacted and portions outside the holes in the panel are mostly expanded, or pairs of thermoelectric elements having metal therebetween are pushed through a hole from one side of an insulating panel exposing a loop of expanded or expandable metal on the other side and retaining the elements within the panel with a variable power supply that is controlled by the user, preferably a universal power supply with a control voltage set by a potentiometer adjustable by the user.

45. The thermoelectric device of claim 44 including a polarity switch for selecting heating or cooling, and/or a thermistor that adjusts the control voltage in response to changes in ambient temperature.
